(19) United States
(12) Patent Application Publication
(10) Pub. No.: US 2014/0185222 A1
(43) Pub. Date: Jul. 3, 2014

(54) ELECTRONIC DEVICE AND METHOD FOR ADJUSTING DISPLAY SCREEN

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: JIAN-HUNG HUNG, New Taipei (TW); MIN YANG, Wuhan (CN)

(73) Assignees: HON HAI PRECISION INDUSTRY CO., LTD., New Taipei (TW); HONG FU JIN PRECISION INDUSTRY (WuHan) CO., LTD., Wuhan (CN)

(21) Appl. No.: 14/135,411

(22) Filed: Dec. 19, 2013

(30) Foreign Application Priority Data
Dec. 28, 2012 (CN) 2012105868990

(51) Int. Cl. H05K 5/00

(52) U.S. Cl. CPC H05K 5/0017
USPC 361/679.22

(57) ABSTRACT

In a method for adjusting a display screen of an electronic device, the method receives first rotation directions and first rotation angles of a handheld device, and rotates the display screen according to the first rotation directions and the first rotation angles. The method further obtains second rotation angles of the display screen detected by a gravity sensor of the electronic device, and stops rotating the display screen when the second rotation angles are equal to the first rotation angles.

### BACKGROUND

1. Technical Field

Embodiments of the present disclosure relate to automatic control technology, and particularly to an electronic device and a method for adjusting a display screen of the electronic device.

2. Description of Related Art

Currently, a position of a display screen is often fixed in use on an electronic device. The position of a display screen cannot be changed according to a movement of another electronic device. Therefore, a method for adjusting a display screen of an electronic device using a handheld device is desired.

### BRIEF DESCRIPTION OF THE DRAWINGS

FIG. 1 is a block diagram of one embodiment of an electronic device including a display screen adjusting system.

FIG. 2 is a block diagram of function modules of the display screen adjusting system included in the electronic device.

FIG. 3 is a flowchart of one embodiment of a method for adjusting a display screen of the electronic device.

FIG. 4 is a schematic diagram of a front view of the display screen.

FIG. 5 is a schematic diagram of a side view of the display screen.

### DETAILED DESCRIPTION

All of the processes described below may be embodied in, and fully automated via, functional code modules executed by one or more general purpose electronic devices or processors. The code modules may be stored in any type of non-transitory computer-readable medium or other storage device. Some or all of the methods may alternatively be embodied in specialized hardware. Depending on the embodiment, the non-transitory computer-readable medium may be a hard disk drive, a compact disc, a digital video disc, a tape drive or other suitable storage medium.

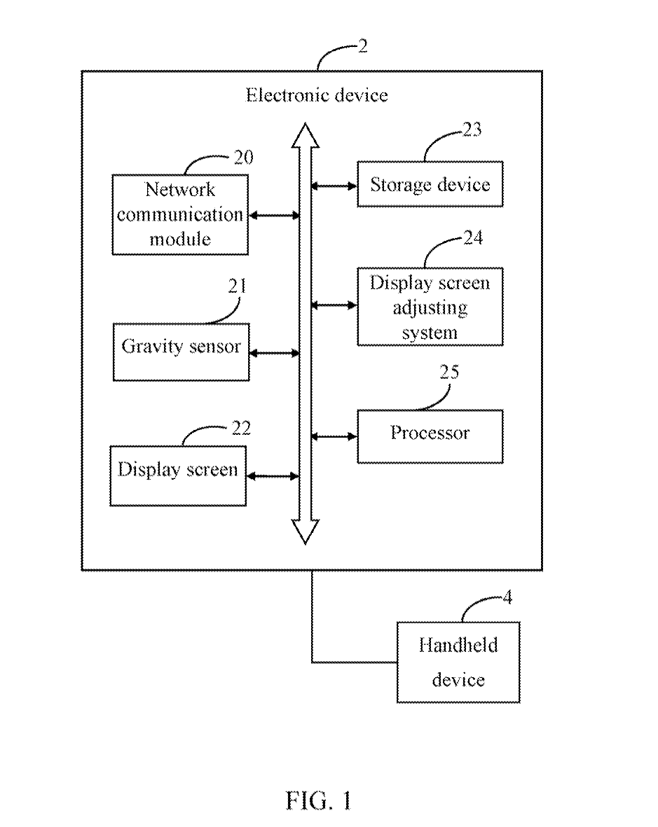

FIG. 1 is a block diagram of one embodiment of an electronic device 2 including a display screen adjusting system 24. The electronic device 2 further includes a network communication module 20, a gravity sensor (G-sensor) 21, a display screen 22, a storage device 23, and at least one processor 25. It should be understood that FIG. 1 illustrates only one example of the electronic device 2 that may include more or fewer components than illustrated, or a different configuration of the various components in other embodiments. In one embodiment, the electronic device 2 may be a desktop computer, a notebook computer, or a server.

The electronic device 2 is connected to a handheld device 4 through the network communication module 20. The network communication module 20 may be a wireless module, such as a WIFI module. A corresponding network communication module is also embedded in the handheld device 4. In one embodiment, the handheld device 4 may be a smart phone, a personal digital assistant (PDA), or other suitable devices.

In one embodiment, the gravity sensor 21 is used to detect rotation angles of the display screen 22 in an X-axis direction, a Y-axis direction, and an Z-axis direction. The processor 25 may be an embedded controller of a single chip micyoco (SCM), such as a 8032 SCM. A working voltage of the processor 25 is three volts.

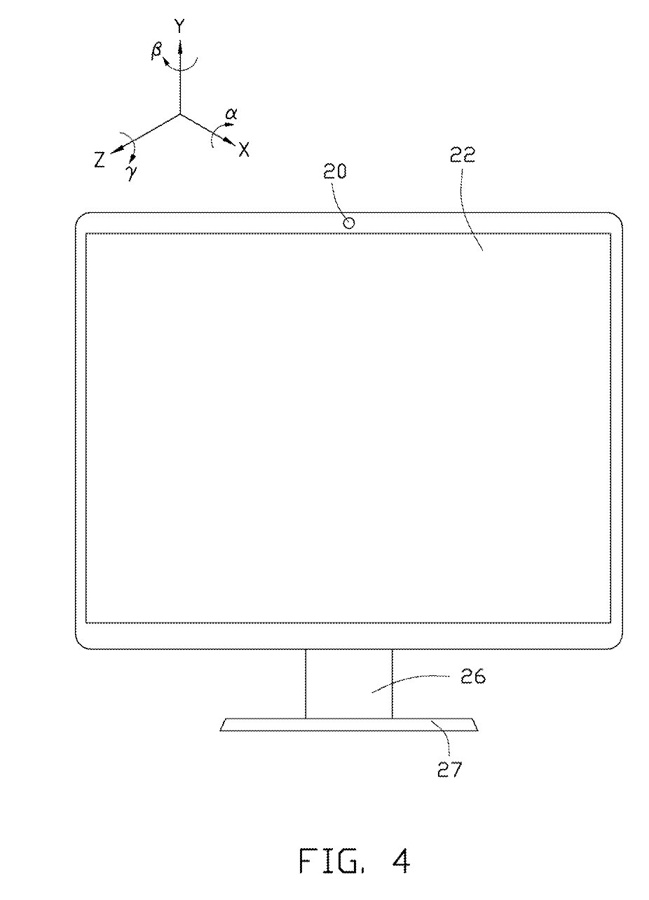

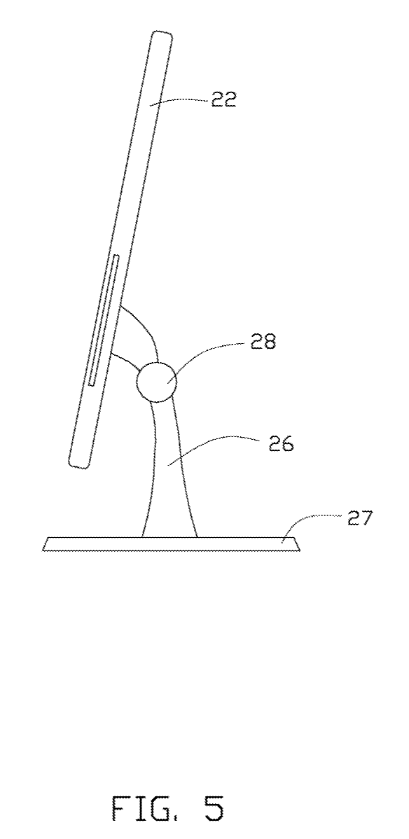

FIG. 4 shows that the network communication module 20 is located on a middle position of a top border of the display screen 22, the display screen 22 is connected with a pedestal 27 through a bracket 26. In addition, as shown in FIG. 5, a rotating bearing 28 is positioned in the bracket 26. The rotating bearing 28 is a spherical bearing. A driving motor is also installed in the bracket 26, and the rotating bearing 28 is rotated using the driving motor, so that the display screen 22 is controlled to rotate in accordance with the rotation of the rotating bearing 28.

In one embodiment, the network communication module 20 is used to communicate with the handheld device 4, and create a communication connection between the electronic device 2 and the handheld device 4, to receive movement data of the handheld device 4 for controlling a rotation of the display screen 22.

The display screen adjusting system 24 is used to receive the movement data of the handheld device 4 via the network communication module 20, and rotate the display screen 22 according to the movement data of the handheld device 4. In one embodiment, the display screen adjusting system 24 may include computerized instructions in the form of one or more programs that are executed by the processor 25 and stored in the storage device 23 (or memory). A detailed description of the display screen adjusting system 24 will be given in the following paragraphs.

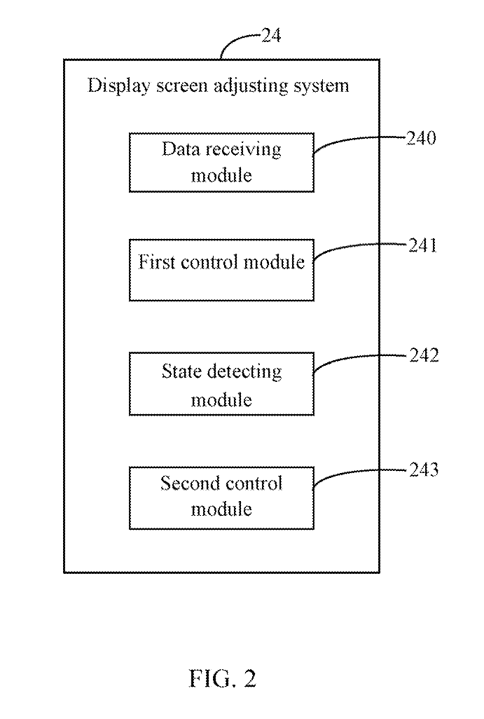

FIG. 2 is a block diagram of function modules of the display screen adjusting system 24 included in the electronic device 2. In one embodiment, the display screen adjusting system 24 may include one or more modules, for example, a data receiving module 240, a first control module 241, a state detecting module 242, and a second control module 243. In general, the word “module”, as used herein, refers to logic embodied in hardware or firmware, or to a collection of software instructions, written in a programming language, such as, Java, C, or assembly. One or more software instructions in the modules may be embedded in firmware, such as in an EPROM. The modules described herein may be implemented as either software and/or hardware modules and may be stored in any type of non-transitory computer-readable medium or other storage device. Some non-limiting examples of non-transitory computer-readable medium include CDs, DVDs, BLU-RAY, flash memory, and hard disk drives.

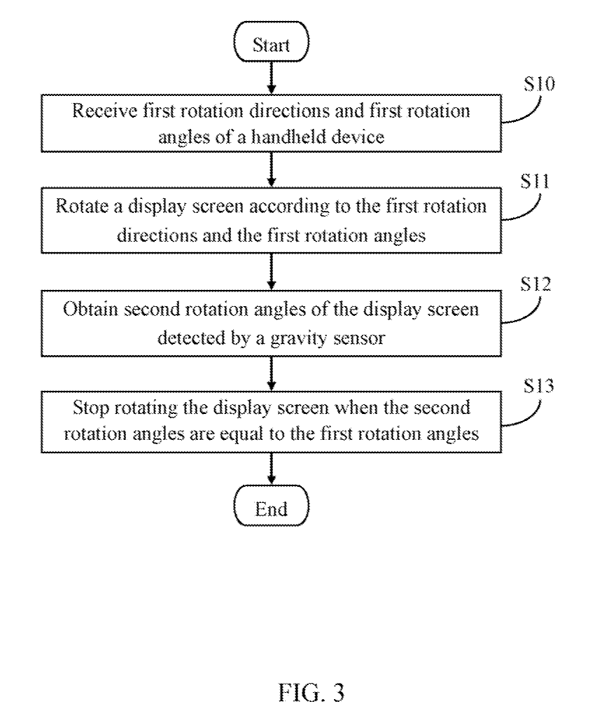

FIG. 3 is a flowchart of one embodiment of a method for adjusting the display screen 22 of the electronic device 2. Depending on the embodiment, additional steps may be added, others removed, and the ordering of the steps may be changed.

Before adjusting the display screen 22, the network communication modules (e.g., wireless modules) in the electronic device 2 and the handheld device 4 are activated, so that a communication connection between the electronic device 2 and the handheld device 4 is created.

In step S10, the data receiving module 240 receives first rotation directions and first rotation angles of the handheld device 4 through the network communication module 20 when the handheld device 4 is rotated. In one embodiment, the first rotation directions may include a first rotation direction in an X-axis of a three dimensional (3D) coordinate system of the handheld device 4 (hereinafter referred to as “first X-axis rotation direction”), a first rotation direction in a Y-axis of the 3D coordinate system of the handheld device 4 (hereinafter referred to as “ first Y-axis rotation direction”), and a first rotation direction in an Z-axis of the 3D coordinate system of the handheld device 4 (hereinafter referred to as “first Z-axis rotation direction”). In one embodiment, the X-axis of the 3D coordinate system of the handheld device 4 is a horizontal direction of a display screen of the handheld device 4, the Y-axis of the 3D coordinate system is a vertical direction of the display screen of the handheld device 4, and the Z-axis of the 3D coordinate system of the handheld device 4 is perpendicular to a plane of the display screen of the handheld device 4.

In one embodiment, the rotation angles may include a first rotation angle in the X-axis (hereinafter referred to as “first X-axis rotation angle”), a first rotation angle in the

Y-axis (hereinafter referred to as “first Y-axis rotation angle”), and a first rotation angle in the Z-axis (hereinafter referred to as “first Z-axis rotation angle”).

In one embodiment, a gravity sensor (G-sensor) is also embedded in the handheld device 4. The gravity sensor is used to detect the first rotation directions and the first rotation angles of the handheld device 4 when the handheld device 4 is rotated, and transmits the first rotation directions and the first rotation angles to the electronic device 2 through the network communication module of the handheld device 4.

In step S11, the first control module 241 rotates the display screen 22 according to the first rotation directions and the first rotation angles of the handheld device 4 by controlling the driving motor installed in the bracket 26 to rotate the rotating bearing 28, and then the display screen 22 is rotated.

For example, the first control module 241 rotates the display screen 22 leftward with the first X-axis rotation angle of the handheld device 4, if the first X-axis movement direction of the handheld device 4 is leftward (e.g., a negative direction of the X-axis). The first control module 241 rotates the display screen 22 rightward with the first X-axis rotation angle of the handheld device 4, if the first X-axis rotation direction of the handheld device 4 is rightward (e.g., a positive direction of the X-axis). The first control module 241 rotates the display screen 22 upward with the first Y-axis rotation angle of the handheld device 4, if the first Y-axis rotation direction of the handheld device 4 is upward (e.g., a positive direction of the Y-axis). The first control module 241 rotates the display screen 22 downward with the first Y-axis rotation angle of the handheld device 4, if the first Y-axis rotation direction of the handheld device 4 is downward (e.g., a negative direction of the Y-axis).

In step S12, the state detecting module 242 obtains second rotation angles of the display screen 22 detected by the gravity sensor 21. In one embodiment, the gravity sensor 21 detects the second rotation angles of the display screen 22 when the display screen 22 is rotated. As shown in FIG. 4, the second rotation angles may include a second rotation angle “α” in an X-axis of a three dimensional (3D) coordinate system of the display screen 22 (hereinafter referred to as “second X-axis rotation angle”), a second rotation angle “β” in a Y-axis of the 3D coordinate system of the display screen 22 (hereinafter referred to as “second Y-axis rotation angle”), and a second rotation angle “γ” in an Z-axis of the 3D coordinate system of the display screen 22 (hereinafter referred to as “second Z-axis rotation angle”).

As shown in FIG. 4, the X-axis of the 3D coordinate system of the display screen 22 is a horizontal direction of the display screen 22, the Y-axis of the 3D coordinate system of the display screen 22 is a vertical direction of the display screen 22, and the Z-axis of the 3D coordinate system of the display screen 22 is perpendicular to a plane of the display screen 22.

In step S13, the second control module 243 stops rotating the display screen 22 when the second rotation angles of the display screen 22 are equal to the first rotation angles of the handheld device 4.

For example, suppose that “a1”, “a2”, and “a3” represent the first X-axis rotation angle, the first Y-axis rotation angle, and the first Z-axis rotation angle of the handheld device 4 respectively, “b1”, “b2”, and “b3” represent the second X-axis rotation angle, the second Y-axis rotation angle, and the second Z-axis rotation angle of the display screen 22 respectively. The second control module 243 stops rotating the display screen 22 when “b1=a1”, “b2=a2”, and “b3=a3”, so that a display direction of the display screen 22 is directly opposite to the user's face, and an optimized visual effect is achieved.

It should be emphasized that the above-described embodiments of the present disclosure, particularly, any embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. A method for adjusting a display screen of an electronic device, the method comprising:
receiving first rotation directions and first rotation angles of a handheld device;
rotating the display screen according to the first rotation directions and the first rotation angles of the handheld device;
obtaining second rotation angles of the display screen detected by a gravity sensor of the electronic device; and
stopping rotating the display screen when the second rotation angles of the display screen are equal to the first rotation angles of the handheld device.

2. The method according to claim 1, wherein the first rotation directions of the handheld device comprise a first X-axis rotation direction, a first Y-axis rotation direction, and a first Z-axis rotation direction of the handheld device, and the first rotation angles of the handheld device comprise a first X-axis rotation angle, a first Y-axis rotation angle, and a first Z-axis rotation angle of the handheld device.

3. The method according to claim 1, wherein the second rotation angles of the display screen comprise a second X-axis rotation angle, a second Y-axis rotation angle, and a second Z-axis rotation angle of the display screen.

4. The method according to claim 1, wherein the display screen is rotated by controlling a driving motor installed in a bracket of the display screen to rotate a rotating bearing of the bracket according to the first rotation directions and the first rotation angles of the handheld device.

5. The method according to claim 4, wherein the rotating bearing of the bracket is a spherical bearing.

6. An electronic device, comprising:
a processor;
a storage device storing a plurality of instructions, which when executed by the processor, causes the processor to:
receive first rotation directions and first rotation angles of a handheld device;
rotate a display screen of the electronic device according to the first rotation directions and the first rotation angles of the handheld device;
obtain second rotation angles of the display screen detected by a gravity sensor of the electronic device; and
stop rotating the display screen when the second rotation angles of the display screen are equal to the first rotation angles of the handheld device.

7. The electronic device according to claim 6, wherein the first rotation directions of the handheld device comprise a first X-axis rotation direction, a first Y-axis rotation direction, and a first Z-axis rotation direction of the handheld device, and the first rotation angles of the handheld device comprise a first X-axis rotation angle, a first Y-axis rotation angle, and a first Z-axis rotation angle of the handheld device.

8. The electronic device according to claim 6, wherein the second rotation angles of the display screen comprise a second X-axis rotation angle, a second Y-axis rotation angle, and a second Z-axis rotation angle of the display screen.

9. The electronic device according to claim 6, wherein the display screen is rotated by controlling a driving motor installed in a bracket of the display screen to rotate a rotating bearing of the bracket according to the first rotation directions and the first rotation angles of the handheld device.

10. The electronic device according to claim 9, wherein the rotating bearing of the bracket is a spherical bearing.

11. A non-transitory storage medium having stored thereon instructions that, when executed by a processor of an electronic device, causes the processor to perform a method for adjusting a display screen of the electronic device, the method comprising:
receiving first rotation directions and first rotation angles of a handheld device;
rotating the display screen according to the first rotation directions and the first rotation angles of the handheld device;
obtaining second rotation angles of the display screen detected by a gravity sensor of the electronic device; and
stopping rotating the display screen when the second rotation angles of the display screen are equal to the first rotation angles of the handheld device.

12. The non-transitory storage medium according to claim 11, wherein the first rotation directions of the handheld device comprise a first X-axis rotation direction, a first Y-axis rotation direction, and a first Z-axis rotation direction of the handheld device, and the first rotation angles of the handheld device comprise a first X-axis rotation angle, a first Y-axis rotation angle, and a first Z-axis rotation angle of the handheld device.

13. The non-transitory storage medium according to claim 11, wherein the second rotation angles of the display screen comprise a second X-axis rotation angle, a second Y-axis rotation angle, and a second Z-axis rotation angle of the display screen.

14. The non-transitory storage medium according to claim 11, wherein the display screen is rotated by controlling a driving motor installed in a bracket of the display screen to rotate a rotating bearing of the bracket according to the first rotation directions and the first rotation angles of the handheld device.

15. The non-transitory storage medium according to claim 14, wherein the rotating bearing of the bracket is a spherical bearing.
